(19) United States
(12) Patent Application Publication
(10) Pub. No.: US 2026/0006939 A1
(43) Pub. Date: Jan. 1, 2026

(54) SOLAR CELL, MULTI-JUNCTION SOLAR CELL, SOLAR CELL MODULE AND PHOTOVOLTAIC POWER GENERATION SYSTEM

(71) Applicant: KABUSHIKI KAISHA TOSHIBA, Kawasaki-shi (JP)

(72) Inventors: Naoyuki NAKAGAWA, Setagaya (JP); Yuya HONISHI, Saitama (JP); Yukitami MIZUNO, Ota (JP); Soichiro SHIBASAKI, Nakano (JP); Atsushi WADA, Kawasaki (JP); Sara YOSHIO, Yokohama (JP); Yasutaka NISHIDA, Tama (JP); Kazushige YAMAMOTO, Yokohama (JP)

(73) Assignee: KABUSHIKI KAISHA TOSHIBA, Kawasaki-shi (JP)

(21) Appl. No.: 19/318,653

(22) Filed: Sep. 4, 2025

Related U.S. Application Data
(63) Continuation of application No. PCT/JP2024/010871, filed on Mar. 19, 2024.

(30) Foreign Application Priority Data
Sep. 20, 2023 (JP) 2023-152083

(51) Int. Cl. H10F 77/12; H10F 10/17; H10F 19/20; H10F 77/164

(52) U.S. Cl. CPC H10F 77/1265; H10F 10/17; H10F 19/20; H10F 77/164

(57) ABSTRACT

A solar cell according to an embodiment includes a p-electrode, an n-electrode, a p-type light-absorbing layer provided on the p-electrode and being mainly composed of a cuprous oxide compound, an n-type layer disposed between the p-type light-absorbing layer and the n-electrode, and a compound of first metal provided between the p-type light-absorbing layer and the n-type layer. Coverage of the compound of the first metal covering the p-type light absorption layer is 10% or more and less than 100%. The first metal is one or more elements selected from the group consisting of Al, Hf, Zr, and B. The cuprous oxide compound is in direct contact with the compound of the first metal and the n-type layer.

### CROSS-REFERENCE TO RELATED APPLICATION

This application is a continuation application based upon and claims the benefit of priority from Japanese Application 2023-152083, the filling Date of which is Sep. 20, 2023, and International Patent Application No. PCT/JP2024/10871, the International Filing Date of which is Mar. 19, 2024, the entire contents of which are incorporated herein by reference.

### FIELD

Embodiments described herein relate generally to a solar cell, a multi-junction solar cell, a solar cell module, and a photovoltaic power generation system.

### BACKGROUND

One of new solar cells is a solar cell using a cuprous oxide (Cu₂O) for a light-absorbing layer. Cu₂O is a wide-gap semiconductor. Since Cu₂O is a safe and inexpensive material including copper and oxygen abundantly present on the earth, it is expected that a high-efficiency and low-cost solar cell can be realized.

### BRIEF DESCRIPTION OF THE DRAWINGS

FIG. 1 is a schematic cross-sectional diagram of a solar cell according to an embodiment;

FIG. 2 shows analysis spots of a solar cell according to an embodiment;

FIG. 3 is a schematic cross-sectional diagram 1 according to an embodiment showing dispersion of first metal;

FIG. 4 is a schematic cross-sectional diagram 1 according to an embodiment showing dispersion of first metal;

FIG. 5 is a schematic cross-sectional diagram 1 according to an embodiment showing dispersion of first metal;

FIG. 6 is a schematic cross-sectional diagram 1 according to an embodiment showing dispersion of first metal;

FIG. 7 is a schematic diagram of a multi-junction solar cell according to an embodiment;

FIG. 8 is a schematic perspective diagram of a solar cell module according to an embodiment;

FIG. 9 is a schematic cross-sectional diagram of a solar cell module according to an embodiment;

FIG. 10 is a structural diagram of a photovoltaic power generation system according to an embodiment;

FIG. 11 is a schematic diagram of a vehicle according to an embodiment;

FIG. 12 is a schematic diagram of a flying object according to an embodiment;

FIG. 13 is a table related to examples;

FIG. 14 is a table related to examples;

FIG. 15 is a table related to examples; and

FIG. 16 is a table related to examples.

### DETAILED DESCRIPTION

A solar cell according to an embodiment includes a p-electrode, an n-electrode, a p-type light-absorbing layer provided on the p-electrode and being mainly composed of a cuprous oxide compound, an n-type layer disposed between the p-type light-absorbing layer and the n-electrode, and a compound of first metal provided between the p-type light-absorbing layer and the n-type layer. Coverage of the compound of the first metal covering the p-type light absorption layer is 10% or more and less than 100%.

The first metal is one or more elements selected from the group consisting of Al, Hf, Zr, and B. The cuprous oxide compound is in direct contact with the compound of the first metal and the n-type layer.

Hereinafter, an embodiment will be described in detail with reference to the drawings. Unless otherwise specified, values at 25° C. and 1 atm (atmosphere) are illustrated. An average represents an arithmetic mean value. Each concentration is an average concentration in the region or layer of interest. In each layer, the presence of a specific element is, for example, an element whose presence is confirmed by SIMS (Secondary Ion Mass Spectrometry), and the absence of a specific element is, for example, an element whose presence cannot be confirmed by SIMS. When the cross-sectional area of a particle in a cross-sectional image is S, the particle diameter of each particle is (4S/π)^{1/2}.

In the specification, “/” (slash) represents the division sign excluding “/” of “and/or”. In the specification, “.” (middle dot, dot operator) represents a multiplication sign. In the (period) of a numerical value represents a specification, “.” (period) of a numerical value represents a decimal point.

### First Embodiment

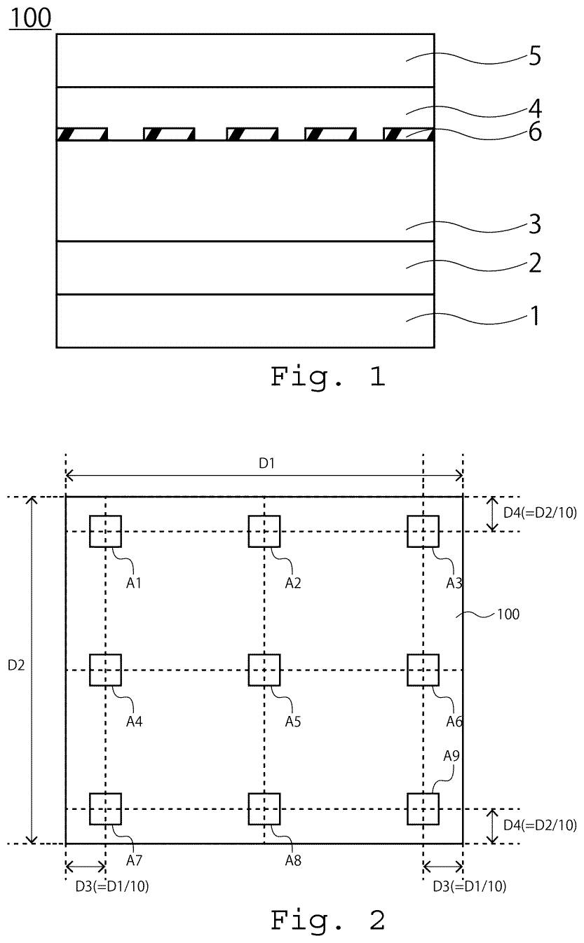

A first embodiment relates to a solar cell. FIG. 1 shows a schematic cross-sectional view of a solar cell 100 of the first embodiment. As shown in FIG. 1, the solar cell 100 of the present embodiment includes a substrate 1, a p-electrode 2 as a first electrode, a p-type light-absorbing layer 3, an n-type layer 4, an n-electrode 5 as a second electrode, and a compound 6 of first metal. An intermediate layer, not shown, may be included between the n-type layer 4 and the n-electrode 5, or the like. Sunlight may be incident from either the n-electrode 5 side or the p-electrode 2 side, but it is more preferably incident from the n-electrode 5 side. Since the solar cell 100 of the embodiment is a transparent solar cell, it is preferable that the solar cell 100 used on the top cell side (Light-incident side) of a multi-junction solar cell. In FIG. 1, the substrate 1 is provided on the side opposite to the p-type light-absorbing layer 3 side of the p-electrode 2, but the substrate 1 may be provided on the side opposite to the n-type layer 4 side of the n-electrode 5. Hereinafter, although a mode illustrated in FIG. 1 will be described, a mode in which the substrate 1 is provided on the n-electrode 5 side except that a position of the substrate 1 is different is also used. In the solar cell 100 of the embodiment, light is incident from the n-electrode 5 side toward the p-electrode 2 side.

The solar cell 100 of the embodiment has a high transmittance of light in the wavelength band of 700 nm or more or 1200 nm or more when the p-electrode 2 and n-electrodes 5 are transmissive, and the solar cell 100 of the embodiment is a red (reddish brown), yellow or orange transparent solar cell in color.

The substrate 1 is a transparent substrate. A transparent organic substrates such as acrylic, polyimide, polycarbonate, polyethylene terephthalate (PET), polypropylene (PP), fluorine-based resins (polytetrafluoroethylene (PTFE), perfluoroethylene, propene copolymer (FEP), ethylene tetrafluoroethylene copolymer (ETFE), polychlorotrifluoroethylene (PCTFE), perfluoroalkoxy alkane (PFA), and the like), polyarylate, polysulfone, polyethersulfone, and polyetherimide and inorganic substrates such as soda lime glass, white glass, chemically strengthened glass, and quartz can be used as the substrate 1. As the substrate 1, the substrates listed above can be laminated.

The p-electrode 2 is provided on the substrate 1 and is disposed between the substrate 1 and the p-type light-absorbing layer 3. The p-electrode 2 preferably forms ohmic contact with the p-type light-absorbing layer 3. The p-electrode 2 is a conductive layer having transparency provided on the p-type light-absorbing layer 3 side. A thickness of the p-electrode 2 is typically 100 [nm] or more and 2000 [nm] or less. In FIG. 1, the p-electrode 2 is in direct contact with the p-type light-absorbing layer 3. It is preferable that the p-electrode 2 includes one or more layers of transparent conductive oxide films. The transparent conductive oxide film is not particularly limited, and is an indium tin oxide (ITO), an Al-doped zinc oxide (AZO), a boron-doped zinc oxide (BZO), a gallium-doped zinc Oxide (GZO), a doped tin oxide, a titanium-doped indium oxide (ITiO), an indium zinc oxide (IZO), an indium gallium zinc oxide (IGZO), a hydrogen-doped indium oxide (IOH), or the like. The transparent conductive oxide film may be a stacked film having a plurality of films. A dopant for a film of tin oxide or the like is not particularly limited as long as the dopant is one or more elements selected from the group consisting of In, Si, Ge, Ti, Cu, Sb, Nb, Ta, W, Mo, F, Cl, and the like. It is preferable that the p-electrode is the doped tin oxide which is doped with one or more elements selected from the group consisting of In, Si, Ge, Ti, Cu, Sb, Nb, Ta, W, Mo, F, Cl, and the like. In the doped tin oxide film, one or more elements selected from the group consisting of In, Si, Ge, Ti, Cu, Sb, Nb, Ta, W, Mo, F, Cl, and the like are preferably contained at 10 [atom %] or less with respect to tin contained in the tin oxide film. As the p-electrode 2, a stacked film of the transparent conductive film and a metal film is preferably used. A thickness of the metal film is preferably 1 [nm] or more and 2 [μm] (micrometre) or less. Metal (including alloy) included in the metal film is not limited to Mo, Au, Cu, Ag, Al, Ta, W or the like. It is preferable that the p-electrode 2 includes a dot-shaped, line-shaped, or mesh-shaped electrode (one or more selected from the group consisting of metal, an alloy, graphene, a conductive nitride, and a conductive oxide) between the transparent d the substrate 1 or between the conductive oxide film and transparent conductive oxide film and the p-type light-absorbing layer 3. It is preferable that the dot-shaped, line-shaped, or mesh-shaped metal has an aperture ratio of 50% or more with respect to an area of the transparent conductive oxide film. The dot-like, line-like, or mesh-like metal is not particularly limited to, and is Mo, Au, Cu, Ag, Al, Ta, W, or the like. When the metal film is used for the p-electrode 2, it is preferable that a film thickness is about 5 or [nm] less from the viewpoint of transparency. When the line-shaped or mesh-shaped metal film is used, since the transparency is secured at an opening, the film thickness of the metal film is not limited to the above range.

It is preferable that a doped tin oxide film, which forms an ohmic junction with the p-type light-absorbing layer 3, is provided on the uppermost surface of the transparent conductive oxide film on the p-type light-absorbing layer 3 side. It is preferable that at least part of the doped tin oxide film on the uppermost surface of the transparent conductive oxide film on the p-type light-absorbing layer 3 side is in direct contact with the p-type light-absorbing layer 3.

The p-type light-absorbing layer 3 is a p-type semiconductor layer. The p-type light-absorbing layer 3 is provided on the p-electrode 2. The p-type light-absorbing layer 3 may be in direct contact with the p-electrode 2, or other layers may be present between the p-type light-absorbing layer and the p-electrode as long as electrical contact with the p-electrode 2 can be ensured. Part of the surface of the p-type light-absorbing layer 3 facing the n-type layer 4 in which the part of the surface is not the entire surface of the p-type light-absorbing layer 3 facing the n-type layer 4, is in direct contact with the n-type layer 4. The p-type light-absorbing layer 3 is mainly composed of a cuprous oxide compound. The cuprous oxide compound preferably has cuprite structure.

The p-type light-absorbing layer 3 is preferably a semiconductor layer including a cuprous oxide compound. The p-type light-absorbing layer 3 is preferably a polycrystalline cuprous oxide compound. The p-type light-absorbing layer 3 may include one or more cuprous oxide impurities selected from the group consisting of copper (Cu), copper oxide (Cu), and copper hydroxide (Cu(OH)₂) as impurities in small quantities.

When all elements in the p-type light-absorbing layer 3 except oxygen element are set as 100%, the copper element in the p-type light-absorbing layer 3 is preferably 90% or more and 100% or less, preferably 95% or more and 100% or less, more preferably 98% or more and 100% or less, and still more preferably 99% or more and 100% or less.

When all elements in the p-type light-absorbing layer 3 except oxygen element are set as 100%, the copper element in the p-type light-absorbing layer 3 is preferably 90% or more and 99.9% or less, preferably 95.0% or more and 99.9% or less, more preferably 98% or more and 99.9% or less, and still more preferably 99.0% or more and 99.9% or less.

The cuprous oxide compound includes copper, oxygen, and optionally an element represented by M1, wherein the element represented by M1 is one or more kinds of elements selected from the group consisting of Cl, F, Br, I, Sn, Sb, Ag, Li, Na, K, Cs, Rb, Al, In, Zn, Mg, Ga, Si, Ge, N, P, B, Ti, Hf, Zr and Ca.

When all elements in the p-type light-absorbing layer 3 except oxygen element are set as 100%, the sum of the copper element and the element represented by M1 in the p-type light-absorbing layer 3 is preferably 90% or more and 100% or less, preferably 95% or more and 100% or less, more preferably 98% or more and 100% or less, and still more preferably 99% or more and 100% or less.

The amount ratio of atoms of oxygen in the cuprous oxide compound is preferably between 0.48 and 0.56 or more when the amount ratio of atoms of copper in the cuprous oxide compound is set to 1. When there are more oxygen atoms relative to copper, the ratio of copper oxide in the cuprous oxide compound becomes higher, resulting in a narrower band gap, which is undesirable because it reduces the translucency of the p-type light-absorbing layer 3. A low ratio of oxygen to copper is not preferable since a high ratio of copper in the cuprous oxide compound may reduce the translucency of the p-type light-absorbing layer 3. When the ratio of oxygen to copper does not satisfy the above range, it becomes difficult for the cuprous oxide compound to have a cuprite structure.

It is preferable that 95 [wt %] or more and 100 [wt %] or less of the p-type light-absorbing layer 3 is the cuprous oxide compound. It is more preferable that 98 [wt %] or more and 100 [wt %] or less of the p-type light-absorbing layer 3 is the cuprous oxide compound. It is still more preferable that 99 [wt %] or more and 100 [wt %] or less of the p-type light absorbing layer 3 is the cuprous oxide compound. 100 [wt %] of the p-type light absorbing layer 3 can be composed of the cuprous oxide compound.

It is preferable that the transmittance of the p-type light-absorbing layer 3 becomes high when content of heterogenous phase included in the p-type light-absorbing layer 3 is little and the crystallinity of the p-type light-absorbing layer 3 is excellent. The band gap of the p-type light-absorbing layer 3 can be adjusted by means, for example, by the inclusion of elements other than Cu and O in the p-type light-absorbing layer 3. The bandgap of the p-type light-absorbing layer 3 is preferably 2.0 [eV] or more and 2.2 [eV] or less. When the bandgap of the p-type light-absorbing layer 3 satisfy above range, both a top cell and bottom cell of a multi-junction solar cell using the solar cell according to the embodiment for the top cell uses sun-light effectively. The p-type light-absorbing layer 3 preferably includes Sn or/and Sb. The Sn and Sb in the p-type light-absorbing layer 3 may be added to the p-type light-absorbing layer 3 or may be derived from the p-electrode 2. The Ga in the p-type light-absorbing layer 3 is not included in the raw material for depositing the p-type light-absorbing layer 3, and the Ga in the n-type layer 4 diffused into the p-type light-absorbing layer 3. When other elements are also used in the deposition of the n-type layer 4, these elements may also diffuse into the p-type light-absorbing layer 3.

The above composition ratio of the p-type light-absorbing layer 3 is an entire composition ratio (average composition ratio) of the p-type light-absorbing layer 3. The above composition ratio of the p-type light-absorbing layer 3 is preferably satisfied in the entire of the p-type light-absorbing layer 3.

The p-type light-absorbing layer 3 preferably includes a p+ type (p plus type) region on the p-electrode 2 side.

The p-type light-absorbing layer 3 preferably includes a p-type (p minus type) region on the n-type layer 4 side. The p-type light-absorbing layer 3 preferably includes the p-type (p minus type) region on the n-type layer 4 side and the p+ type (p plus type) region on the p-electrode 2 side.

When elements included in the n-type layer 4 diffuse into the p-type light-absorbing layer 3 and/or elements included in the p-type light-absorbing layer 3 diffuse into the n-type layer 4, a mixed region between the p-type light-absorbing layer 3 and the n-type layer 4 where the elements are diffused each other whose thickness is 20 [nm] or less may exist. 90 [atom %] or less of the metal elements included in the mixed region is the metal elements included in the p-type light-absorbing layer 3 and 10 [atom %] or more of the metal elements included in the mixed region is the metal elements included in the n-type layer 4. When the mixed region exists, a surface of the p-type light-absorbing layer 3 on the n-type layer 4 side is set at the position of the surface of the compound 6 of the first metal on the p-electrode 2 side.

A thickness of the p-type light-absorbing layer 3 is evaluated by observing a cross-section of electron microscope or step profiler, is preferable 2000 [nm] or more and 15000 [nm] or less (2 [μm] (micrometre) or more and 15 [μm] (micrometre) or less), more preferably 2500 [nm] or more and 10000 [nm] or less, still more preferably 4000 [nm] or more and 10000 [nm] or less, and preferably 4000 [nm] or more and 8000 [nm] or less. A difference of unevenness of the p-type light-absorbing layer 3 is small, and the difference between the minimum thickness of the p-type light-absorbing layer 3 and a maximum thickness of the p-type light-absorbing layer 3 is preferably 0 [nm] or more and 100 [nm] or less and more preferably 0 [nm] or more and 50 [nm] or less. The p-type light-absorbing layer 3 has a rectangular shape.

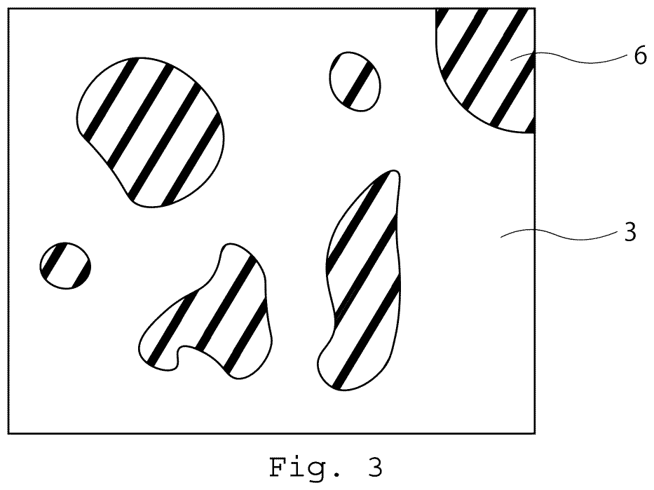

The composition of the p-type light-absorbing layer 3 and others are obtained by analyzing in each cross-sectional image of the analysis spots A1 to A9 which is equally distributed as far as possible as shown in FIG. 2 using, for example, a secondary ion mass spectrometry (SIMS). FIG. 2 is a schematic view of the solar cell 100 from the light is incident side. When the composition of the p-type light absorbing layer 3 is analyzed, D1 is a length of the p-type light absorbing layer 3 in the width direction (longitudinal direction) and D2 is a length of the p-type light-absorbing layer 3 in the depth direction (short direction). The composition analysis is performed, for example, from the surface of the n-type layer 4 toward the p-electrode 2.

The composition of the p-type light-absorbing layer 3 is the average of the composition at depths of 0.1d₁ (multiply 0.1 by d₁), 0.2d₁ (multiply 0.2 by d₁), 0.3d₁ (multiply 0.3 by d₁), 0.4d₁ (multiply 0.4 by d₁), 0.5d₁ (multiply 0.5 by d₁), 0.6d₁ (multiply 0.6 by d₁), 0.7d₁ (multiply 0.7 by d₁), 0.8d₁ (multiply 0.8 by d₁) and 0.9d₁ (multiply 0.9 by d₁) from the surface of the p-type light-absorbing layer 3 on the p-electrode 2 side, when the thickness of p-type light-absorbing layer 3 is designated as d₁. When the analyzing is performed with SIMS, it is preferable to obtain the average composition by analyzing the p-type light-absorbing layer 3 from the 0.1d₁ point because the elements of the n-type layer 4 are easily detected when the surface of the p-type light absorbing layer 3 is analyzed.

The p-type light-absorbing layer 3 is preferably deposited by, for example, a sputtering method. Specifically, it is preferable that the member having the p-electrode 2 formed on the substrate 1 is heated to 300 [° C.] (degrees Celsius) or more and 600 [° C.] (degrees Celsius), and deposition is performed within a range of 0.02 [μm/min] (micrometre per minutes) or more and 20 [μm/min] (micrometre per minutes) or less at an oxygen partial pressure being 0.01 [Pa] or more and 4.8 [Pa] or less. From the viewpoint of depositing a polycrystalline layer with high transparency and large grain size, it is more preferable that the oxygen partial pressure is between 0.55× d (multiply 0.55 by “d”) [Pa] and 1.00×d (multiply 1.00 by “d”) [Pa] when the deposition rate is defined as “d”. The heating temperature is more preferably 350 [° C.] (degrees Celsius) or more and 500 [° C.] (degrees Celsius) or less. The element M1 may be added during deposition. After deposition of the p-type light absorbing layer 3, the side surface on which the compound 6 of the first metal and the n-type layer 4 is formed may be oxidized before forming the compound 6 of the first metal and the n-type layer 4.

The n-type layer 4 is an n-type semiconductor layer. The n-type layer 4 is disposed between the p-type light-absorbing layer 3 and the n-electrode 5. The n-type layer 4 is preferably provided on the p-type light-absorbing layer 3. The n-type layer 4 is deposited by, for example, ALD method.

The n-type layer 4 preferably includes a Ga-based compound (oxide). The n-type layer 4 may be a mixture of the Ga-based oxide with other oxides, or the Ga-based oxide may be doped with other elements, or the Ga-based oxide doped with other elements and other oxides may be mixed. The n-type layer 4 may be a single layer or a multilayer. Among the metallic elements included in the n-type layer 4, it is preferable that Ga content is 40 [atom %] or more, and it is more preferable that the Ga content is 50 [atom %] or more. The metal elements including Ga included in the n-type layer 4 may be graded from the p-type light absorbing layer 3 side to the n-electrode 5 side. When the n-type layer 4 is a multilayer semiconductor layer (e.g., two layers), the first n-type layer is on the p-type light-absorbing layer 3 side and the second n-type layer is on the n-electrode 5 side. The element represented by M2 included in the first n-type layer is preferably less than the element represented by M2 included in the second n-type layer.

The n-type layer 4 preferably includes an oxide including Ga and the element represented by M2. The Ga-based oxide is, for example, an oxide including Ga and the element represented by M2. The n-type layer 4 preferably includes an oxide including Ga and the element represented by M2 which is one or more elements selected from the group consisting of H, Sn, Sb, Cu, Ag, Li, Na, K, Cs, Rb, Al, In, Zn, Mg, Si, Ge, N, B, Ti, Hf, Zr, Ca, Ce, La, Pr and Nd. It is preferable that 90 [wt %] or more and 100 [wt %] or less of the n-type layer 4 is the oxide including Ga and the element represented by M2 which is one or more elements selected from the group consisting of H, Sn, Sb, Cu, Ag, Li, Na, K, Cs, Rb, Al, In, Zn, Mg, Si, Ge, N, B, Ti, Hf, Zr, Ca, Ce, La, Pr and Nd. The Ga-based compound of the n-type layer 4 is preferably an oxide including Ga and the element represented by M2 whose average composition is represented by Gaₕ₁M2ᵢ₁Oⱼ₁. It is preferable that h1, i1 and j2 satisfy 1.8≤h1≤2.1 (h1 is 1.8 or more and 2.1 or less), 0.0≤i1≤0.2 (i1 is 0.0 or more and 0.2 or less), and 2.9≤j1≤3.1 (j1 is 2.9 or more and 3.1 or less).

90 [wt %] or more and 100 [wt %] or less of the n-type layer 4 is preferably the oxide including Ga and the element represented by M2. 95 [wt %] or more and 100 [wt %] or less of the n-type layer 4 is more preferably the oxide including Ga and the element represented by M2. 98 [wt %] or more and 100 [wt %] or less of the n-type layer 4 is still more preferably the oxide including Ga and the element represented by M2. Cu included in the n-type layer 4 is not included in the raw material for forming the n-type layer 4, and Cu included in the p-type light-absorbing layer 3 is diffused into the n-type layer 4. When other elements are used for the depositing the p-type light-absorbing layer 3, these elements may also diffuse into the n-type layer 4.

The thickness of the n-type layer 4 is typically 3 [nm] or more and 100 [nm] or less. When the thickness of the n-type layer 4 is less than 3 [nm], leakage current may occur when the coverage of the n-type layer 4 is poor, and the characteristics may be degraded. When the coverage is good, the thickness is not limited to the above thickness of the n-type layer 4. When the thickness of the n-type layer 4 exceeds 50 [nm], the characteristics may be degraded due to excessively high resistance of the n-type layer 4 and the short circuit current may be reduced due to decreased transmittance. Therefore, the thickness of the n-type layer 4 is more preferably 3 [nm] or more and 20 [nm] or less, and more preferably 5 [nm] or more and 20 [nm] or less.

Incidentally, the composition of the compound of the n-type layer 4 is an average composition of the entire n-type layer 4 unless any particular condition is specified. The composition of the n-type layer 4 is an average value of the composition at the depth of 0.2d₄ (multiply 0.2 by d₄), 0.5d₄ (multiply 0.5 by d₄), and 0.8d₄ (multiply 0.8 by d₄) from the surface of the n-type layer 4 on the p-type light-absorbing layer 3 side when the thickness of the n-type layer 4 is designated as d₄. At each depth, the n-type layer 4 preferably satisfies the above and the following suitable compositions, except in cases where there are conditions such as a gradient in the elemental composition ratio of the compound of n-type layer 4. When the n-type layer 4 is very thin (e.g., 5 [nm] or less), the composition at a depth of 0.5d₄ from the surface of the n-type layer 4 on the p-type light-absorbing layer 3 side can be regarded as the overall composition of the n-type layer 4. Analysts of the n-type layer 4 is performed by analyzing in each cross-sectional image of the analysis spots A1 to A9 which is equally distributed as far as possible as shown in FIG. 2 using, for example, a secondary ion mass spectrometry (SIMS). FIG. 2 is a schematic view of the solar cell 100 from the light is incident side. When the n-type layer 4 is analyzed, D1 is a length (longitudinal direction) of the n-type layer 4 in the width direction and D2 is a length of the n-type layer 4 in the depth direction (short direction).

An average composition of a region from the surface of the n-type layer 4 on the p-type light-absorbing layer 3 side (start point) to 1 [nm] (end point) toward the n-electrode 5 is represented by Gaₕ₂M3ᵢ₂Oⱼ₂. It is preferable that “h2”, “i2”, and “j2” satisfy 1.8≤h2≤2.1 (h2 is 1.8 or more and 2.1 or less), 0.00≤i2≤0.05 (i2 is 0.00 or more and 0.05 or less), and 2.9≤ j2≤3.1 (j2 is 2.9 or more and 3.1 or less). It is more preferable that “h2”, “i2”, and “j2” satisfy 1.8≤h2≤2.1 (h2 is 1.8 or more and 2.1 or less), 0.00≤i2≤0.03 (i2 is 0.00 or more and 0.03 or less), and 2.9≤j2≤3.1 (j2 is 2.9 or more and 3.1 or less). It is still more preferable 1.8≤h2≤2.1 (h2 is 1.8 or more and 2.1 or less), 0.00≤i2≤0.01 (i2 is 0.00 or more and 0.01 or less), and 2.9≤j2≤3.1 (j2 is 2.9 or more and 3.1 or less). The element represented by M3 is preferably one or more elements selected from the group consisting of H, Sn, Sb, Cu, Ag, Li, Na, K, Cs, Rb, Al, In, Zn, Mg, Si, Ge, N, B, Ti, Hf, Zr, Ca, Ce, La, Pr, and Nd. The element represented by M3 is preferably one or more elements selected from the group consisting of H, Sn, Sb, Cu, Ag, Li, Na, K, Cs, Rb, In, Zn, Mg, Si, Ge, N, Ti, Ca, Ce, La, Pr, and Nd. It is preferable that h2, 12, and j2 satisfy 1.8≤h2≤2.1 (h2 is 1.8 or more and 2.1 or less), 12=0, and 2.9≤ j2<3.1 (j2 is 2.9 or more and 3.1 or less) in the region from the surface of the n-type layer 4 on the p-type light-absorbing layer 3 side (start point) to 1 [nm] (end point) toward the n-electrode 5.

The compound 6 of the first metal is provided between the p-type light-absorbing layer 3 and the n-type layer 4. The cuprous oxide compound is preferably in direct contact with the p-type light-absorbing layer 3 and the n-type layer 4. It is preferable that the compound 6 of the first metal is distributed in an island-like pattern between the p-type light-absorbing layer 3 and the n-type layer 4. It is more preferably that the side of the compound 6 of the first metal facing the p-type light-absorbing layer 3 is in direct contact with the p-type light-absorbing layer 3. It is more preferably that one or more side surfaces of the compound 6 of the first metal which does not face the p-type light-absorbing layer 3 are in direct contact with the n-type layer 4. It is more preferably that every side surface of the compound 6 of the first metal which does not face the p-type light-absorbing layer 3 is in direct contact with the n-type layer 4. Coverage of the compound 6 of the first metal covering the p-type light-absorbing layer 3 (the area of the compound 6 of the first metal in contact with the p-type light-absorbing layer 3 relatives to the area of the surface of the p-type light-absorbing layer 3 facing the n-type layer 4) is preferably 10% or more and less than 100%. In other words, the compound 6 of the first metal has side surfaces (which faces each other). The side surface of the compound 6 of the first metal is preferably in direct contact with the p-type light-absorbing layer 3 and/or the n-type layer 4. In the part where the compound 6 of the first metal is not present, the p-type light absorbing layer 3 is in direct with the n-type layer 4.

The compound 6 of the first metal is preferably present to spread in the plane direction on the n-type layer 4 side of the p-type light-absorbing layer 3. The compound 6 of the first metal is preferably present to spread in the plane direction on the n-type layer 4 side of the p-type light-absorbing layer 3. The compound 6 of the first metal is preferably not present in the interior of the p-type light-absorbing layer 3 and in the interior of the n-type layer 4. In other words, it is preferable that the compound 6 of the first metal that is not in contact with the surface of the p-type light-absorbing layer 3 is not present in the solar cell 100. In other words, it is preferable that the compound 6 of the first metal that is not in contact with the surface of the n-type layer 4 is not present in the solar cell 100.

The compound 6 of the first metal is preferably an insulating material. The compound 6 of the first metal is a material that is insulating in the stacking direction (stacking direction of the p-type light absorbing layer 3 and the n-type layer 4). The compound 6 of the first metal is preferably an oxide of the first metal, a nitride of the first metal, or a sulfide of the first metal. The compound 6 of the first metal preferably consists of the oxide of the first metal, the nitride of the first metal, or the sulfide of the first metal. Since the compound 6 of the first metal is present in an extremely small area, when the compound 6 of the first metal is the oxide, it is difficult to determine whether the oxygen at the edge of the area where the compound 6 of the first metal is present is regarded as the oxygen of the n-type layer 4 or the oxygen of the compound 6 of the first metal. Therefore, when expressing the composition of the compound 6 of the first metal in the embodiment and examples, the composition of the compound of the first metal (For example, Alₓ₁Hfₓ₂Zrₓ₃Bₓ₄O_{y}, Alₓ₁O_{y}, Hfₓ₂O_{y}, Zrₓ₃O_{y}, Bₓ₄O_{y}, and the like described in embodiments and examples satisfy following ranges of values) is expressed in the following numerical range.

The compound 6 of the first metal is preferably the oxide of the first metal. The compound 6 of the first metal preferably is composed of the oxide of the first metal.

The first metal (element) is preferably one or more elements selected from the group consisting to Al, Hf, Zr, and B. The first metal (element) is preferably Al, Hf, Zr, or B.

The compound 6 of the first metal is preferably a compound represented by Alₓ₁Hfₓ₂Zrₓ₃Bₓ₄O_{y}. “x1”, “x2”, “x3”, “x4”, and “y” preferably satisfy 0.8<x1+x2+x3+x4≤1.2 (sum of x1, x2, x3, and x4 is 0.8 or more and 1.2 or less) and 0.3≤(x1+x2+x3+x4)/y≤0.8 ([(x1+x2+x3+x4)/y] is 0.3 or more and 0.8 or less), and more preferably satisfy 0.9≤x1+x2+x3+x4≤1.1 (sum of x1, x2, x3, and x4 is 0.9 or more and 1.1 or less) and 0.4≤(x1+x2+x3+x4)/y≤0.7 ([(x1+x2+x3+x4)/y]is 0.4 or more and 0.7 or less), and still more preferably satisfy 0.95≤x1+x2+x3+x4≤1.15 (sum of x1, x2, x3, and x4 is 0.95 or more and 1.15 or less) and 0.6≤(x1+x2+x3+x4)/y≤0.7 ([(x1+x2+x3+x4)/y] is 0.6 or more and 0.7 or less).

When the compound 6 of the first metal is a compound represented by Alₓ₁Hfₓ₂Zrₓ₃Bₓ₄O_{y} and the compound 6 of the first metal is mainly composed of Al, “x1”, “x2”, “x3”, and “x4” preferably satisfy 0.8≤x1/(x1+x2+x3+x4)≤1.0 ([x1/(x1+x2+x3+x4)]) is 0.8 or more and 1.0 or less) and 0.9≤x1/(x1+x2+x3+x4)≤1.0 ([x1/(x1+x2+x3+x4)]) is 0.9 or more and 1.0 or less).

It is preferable that the compound 6 of the first metal is a compound represented by Al O_{y}. When the compound 6 of the first metal is the compound represented by Alₓ₁O_{y}, “x1” and “y” preferably satisfy 0.5≤x1/y≤0.8 ([x1/y] is 0.5 or more and 0.8 or less), and more preferably satisfy 0.6≤x1/y≤0.7 ([x1/y] is 0.6 or more and 0.7 or less).

When the compound 6 of the first metal is a compound represented by Alₓ₁Hfₓ₂Zrₓ₃Bₓ₄O_{y} and the compound 6 of the first metal is mainly composed of Hf, “x1”, “x2”, “x3”, and “x4” preferably satisfy 0.8<x2/(x1+x2+x3+x4)≤1.0 ([x2/(x1+x2+x3+x4)]) is 0.8 or more and 1.0 or less) and 0.9≤x2/(x1+x2+x3+x4)≤1.0 ([x2/(x1+x2+x3+x4)]) is 0.9 or more and 1.0 or less).

It is preferable that the compound 6 of the first metal is a compound represented by Hfₓ₂O_{y}. When the compound 6 of the first metal is the compound represented by Hf O_{y}, “x2” and “y” preferably satisfy 0.3≤x2/y≤0.7 ([x2/y] is 0.3 or more and 0.7 or less), and more preferably satisfy 0.4≤x2/y≤0.6 ([x2/y] is 0.4 or more and 0.6 or less).

When the compound 6 of the first metal is a compound represented by Alₓ₁Hfₓ₂Zrₓ₃Bₓ₄O_{y} and the compound 6 of the first metal is mainly composed of Zr, “x1”, “x2”, “x3”, and “x4” preferably satisfy 0.8≤x3/(x1+x2+x3+x4)≤1.0 ([x3/(x1+x2+x3+x4)]) is 0.8 or more and 1.0 or less) and 0.9≤x3/(x1+x2+x3+x4)≤1.0 ([x3/(x1+x2+x3+x4)]) is 0.9 or more and 1.0 or less).

It is preferable that the compound 6 of the first metal is a compound represented by Zrₓ₃O_{y}. When the compound 6 of the first metal is the compound represented by Zrₓ₃O_{y}, “x3” and “y” preferably satisfy 0.3≤x3/y≤0.7 ([x3/y] is 0.3 or more and 0.7 or less), and more preferably satisfy 0.4≤x3/y≤0.6 ([x3/y] is 0.4 or more and 0.6 or less).

When the compound 6 of the first metal is a compound represented by Alₓ₁Hfₓ₂Zrₓ₃Bₓ₄O_{y} and the compound 6 of the first metal is mainly composed of B, “x1”, “x2”, “x3”, and “x4” preferably satisfy 0.8≤x4/(x1+x2+x3+x4)≤1.0 ([x4/(x1+x2+x3+x4)]) is 0.8 or more and 1.0 or less) and 0.9≤x4/(x1+x2+x3+x4)≤1.0 ([x4/(x1+x2+x3+x4)]) is 0.9 or more and 1.0 or less).

It is preferable that the compound 6 of the first metal is a compound represented by Bₓ₄O_{y}. When the compound 6 of the first metal is the compound represented by Alₓ₁O_{y}, “x4” and “y” preferably satisfy 0.5≤x4/y≤0.8 ([x1/y] is 0.5 or more and 0.8 or less), and more preferably satisfy 0.6≤x4/y≤0.7 ([x1/y] is 0.6 or more and 0.7 or less).

The compound 6 of the first metal used in the example also satisfies the preferred conditions for “x1”, “x2”, “x3”, “x4” and “y” above.

The coverage (the coverage of the compound 6 of the first metal covering the p-type light-absorbing layer 3 (the area of the compound 6 of the first metal in contact with the p-type light-absorbing layer 3 relative to the area of the surface of the p-type light-absorbing layer 3 facing the n-type layer 4)) is less than 100% and the compound 6 of the first metal is present between the p-type light absorbing layer 3 and the n-type layer 4, which contributes to both a high fill factor (FF) and a high open circuit voltage (Voc), thereby contributing to the improvement of the conversion efficiency of the solar cell.

Since the oxygen of the cuprous oxide compound on the surface of the p-type light-absorbing layer 3 of the embodiment is less likely to be drawn out by the n-type layer 4 than in the solar cell without the compound 6 of the first metal, even if defects exist on the surface of the p-type light-absorbing layer 3, the number of defects in the p-type light-absorbing layer 3 with the compound 6 of the first metal becomes smaller than that in a p-type light-absorbing layer without the compound 6 of the first metal, which may contribute to the improvement of conversion efficiency.

Oxygen in the cuprous oxide compound is easily drawn out by the n-type layer 4, but it is thought that the compound 6 of the first metal inhibits the oxygen in the cuprous oxide compound from being drawn out. When the n-type layer 4, which is thicker than the compound 6 of the first metal, is formed after the compound 6 of the first metal is formed, it is thought that the n-type layer 4 inhibits drawing oxygen from the cuprous oxide compound since the stability of the compound 6 of the first metal is high and a part of the surface of the p-type light-absorbing layer 3 is covered by the compound 6 of the first metal. This is thought to inhibit the n-type layer 4 from drawing oxygen out of the cuprous oxide compound. Then, the n-type layer 4 can be formed while inhibiting the formation of surface defects in the already formed cuprous oxide compound.

An average thickness of the compound 6 of the first metal is preferably 0.2 [nm] or more and 1 [nm] (a thickness equivalent to about 1 atomic layer) or less, since a thicker compound of the first metal makes it difficult to extract the light carriers generated in the p-type light-absorbing layer 3 to the n-type layer 4. From the same viewpoint, a maximum thickness of the compound 6 of the first metal is preferably 0.2 [nm] or more and 1 [nm] or less, and more preferably 0.4 [nm] or more and 0.8 [nm] or less. The thickness of the compound 6 of the first metal is measured by observing the same spots as A1 to A9 with a TEM (transmission electron microscope) at a high magnification (e.g., 1 million times).

From the viewpoint of the transmittance of the solar cell 100, the compound 6 of the first metal should have a wide bandgap that satisfies the above thickness. Therefore, the band gap of the compound 6 of the first metal is preferably 5 [eV] or more and 10 [eV] or less, and more preferably 6 [eV] or more and 9 [eV] or less.

The portion where the compound 6 of the first metal is present on the p-type light-absorbing layer 3 preferably has a repeated pattern in which the first metal and oxygen are bonded together. In the areas where the compound 6 of the first metal is not present on the p-type light-absorbing layer 3, when the n-type layer 4 contains gallium and oxygen, the pattern in which gallium and oxygen are bonded is preferably repeated. When a pattern in which the first metal, oxygen and gallium are bonded is randomly repeated entirely without regularity, the oxide layer formed on the p-type light-absorbing layer 3 is, for example, an oxide of Ga and Al, which is different from the configuration of the embodiment.

A passivation film may be used between the p-n interface of the solar cell, and a thickness of the passivation film is, for example, 3 [nm] or more. Such a thick film may be formed over a CIGS film with a chalcopyrite structure. If a light-absorbing layer is a CIGS film with a chalcopyrite structure, the characteristics of the solar cell will not be deteriorated with using a compound 6 of the first metal of the embodiment whose thickness is so thick that it does not meet the above range due to differences in compositional elements including composition ratio of the light-absorbing layer. However, when the passivation film with a thickness of 3 [nm] or more, which is used in other solar cells including CIGS films, is used between the p-type light absorbing layer 3 and n-type layer 4 of the Cu₂O solar cell, it is found that Jsc, Voc, FF and conversion efficiency all decrease significantly, although transmission is good. The compound 6 of the first metal is intentionally open (the coverage is less than 100%) and its thickness is very thin, which is different from the passivation film. The compound 6 of the first metal can be extremely thin, since its only target material is to inhibit the withdrawal of oxygen from the p-type light-absorbing layer 3 by the n-type layer 4.

From the above viewpoint, the coverage is more preferably 10% or more and less than 100%, preferably 20% or more and 80% or less, and more preferably 30% or more and 60% or less. As the thickness of the compound 6 of the first metal provided on the p-type light-absorbing layer 3 increases, the FF gradually decreases, and when the thickness of the compound 6 of the first metal exceeds substantially one atomic layer, the Jsc also decreases. When the thickness of the compound 6 of the first metal on the p-type light-absorbing layer 3 becomes about 2 atomic layers, Voc is high, but Jsc and FF decrease markedly, which results that conversion efficiency is decreased. Even when the thickness of the compound 6 of the first metal is sufficiently thin, the coverage rate is preferably 10% or more, since Voc is not substantially improved due to a low coverage rate. The coverage and the composition of the compound 6 of the first metal are determined by removing the n-electrode 5 of the solar cell 100 by ion milling, etc. and analyzing it from the n-type layer 4 side by HAXPES (hard X-ray photoelectron spectroscopy).

The compound 6 of the first metal is preferably formed on the p-type light-absorbing layer 3, for example, by the ALD method. It is preferable that the n-type layer 4 is formed on the p-type light-absorbing layer 3 on which the compound 6 of the first metal is formed on a part of the surface of the p-type light-absorbing layer 3.

It is preferable that one or more compounds selected from the group consisting of trimethylaluminum, triethylaluminum, tris(dimethylamido) aluminum, tri (ethoxy)aluminum, tetrakis(dimethylamino) hafnium, tetrakis(ethylmethylamino) hafnium, tetrakis(diethylamino) hafnium, tetrakis(dimethylamino) zirconium, tetrakis(ethylmethylamino) zirconium, tetrakis(diethylamino) zirconium, triethylboron, tris(dimethylamino) borane for forming the compound 6 of the first metal in the ALD method. It is preferable to adjust the pulse irradiation time and other factors when forming the compound 6 of the first metal by the ALD method to form 1 [nm] or less, for example, less than 1 atomic layer of the compound 6 of the first metal, on the entire surface of the p-type light-absorbing layer 3 on the side where the n-type layer 4 will be formed.

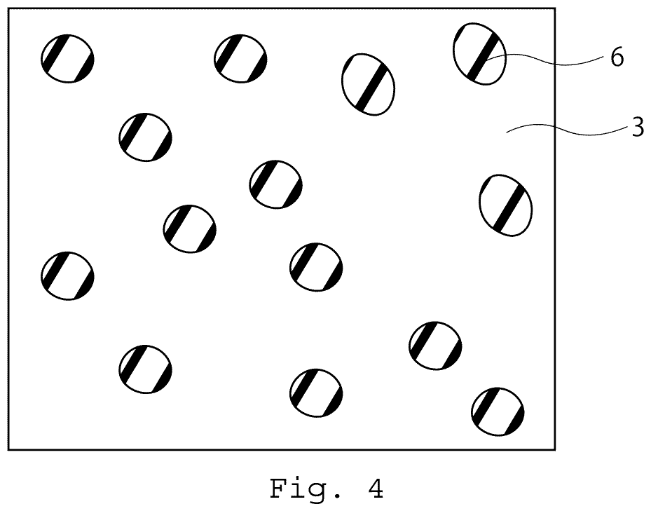

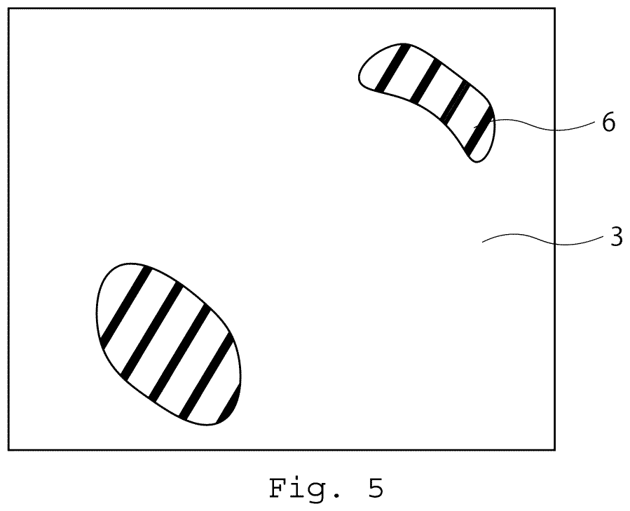

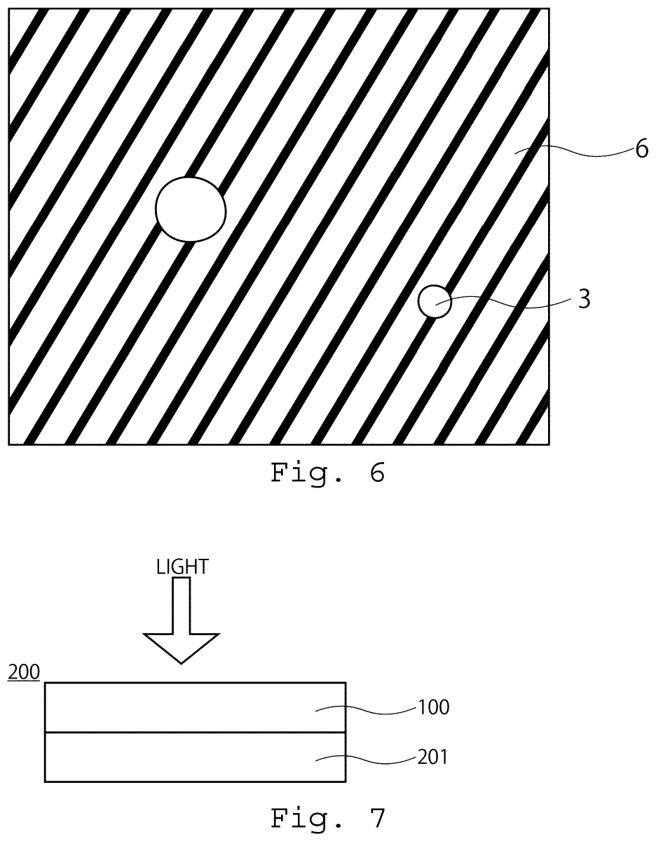

The distribution of the compound 6 of the first metal is schematically shown in FIG. 3, FIG. 4, FIG. 5, and FIG. 6. As shown in the figures, the pattern of the dispersion of the compound 6 of the first metal is not limited. High dispersion of the compound 6 of the first metal is preferred, but the compound 6 of the first metal whose dispersibility is low, as shown in FIG. 3, also contributes to improvement of conversion efficiency. The island-like pattern dispersion as shown in the figure is interpreted in a broad sense. For example, the average area of the island of the compound 6 of the first metal is preferably 3% or more and less than 100% of the area of the surface of the p-type light-absorbing layer 3 on the n-type layer 4 side, and more preferably 5% or more and 90% or less of the area of the surface of the p-type light-absorbing layer 3 on the n-type layer 4 side, and still more preferably 10% or more and 90% or less of the area of the surface of the p-type light-absorbing layer 3 on the n-type layer 4 side.

The n-electrode 5 is the electrode on the n-type layer 4 side that has light transmittance for visible light. The n-electrode 5 is preferably provided on the n-type layer 4. The n-electrode 5 and the p-type light-absorbing layer 3 sandwich the n-type layer 4 and the compound 6 of the first metal. An intermediate layer not shown can be provided between the n-type layer 4 and the n-electrode 5. A transparent conductive oxide film is preferably used for the n-electrode 5. The transparent conductive oxide film used in the n-electrode 5 is a semiconductor conductive film of one or more selected from the group consisting of indium tin oxide, aluminum-doped zinc oxide, boron-doped zinc oxide, gallium-doped zinc oxide, indium-doped zinc oxide, titanium-doped indium oxide, indium gallium zinc oxide and hydrogen-doped indium oxide. Dopants for tin oxide and other films are not limited to one or more elements selected from the group consisting of In, Si, Ge, Ti, Cu, Sb, Nb, Ta, W, Mo, F, Cl, and the like. The n-electrode 5 can include a mesh-shaped electrode or a line-shaped electrode to lower the resistance of the transparent conductive oxide film. The mesh-shape and line-shaped electrode are not limited to Mo, Au, Cu, Ag, Al, Ta, or W. Graphene can also be used for the n-electrode 5. Graphene is preferably stacked with silver nanowires.

The thickness of the n-electrode 5 is obtained by cross-sectional observation with an electron microscope or by a step profiler, and is not particularly limited, but is typically 50 [nm] or more and 2 [μm] (micrometre) or less.

The n-electrode 5 is preferably deposited by, for example, sputtering.

### Second Embodiment

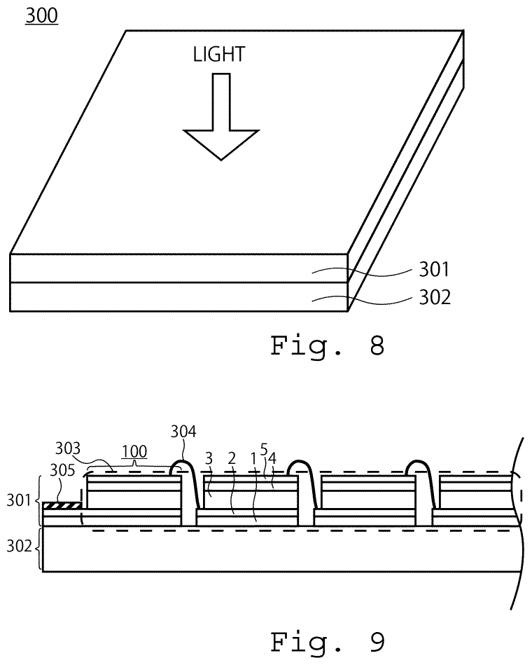

A second embodiment relates to a multi-junction solar cell. FIG. 7 shows a cross-sectional diagram of the multi-junction solar cell of the second embodiment. The multi-junction solar cell 200 of FIG. 7 has the solar cell 100 of the first embodiment (first solar cell) on the light is incident side and the second solar cell 201. The band gap of a light-absorbing layer of the second solar cell 201 has a smaller band gap than the p-type light-absorbing layer 3 of the solar cell 100 of the first embodiment. The multi-junction solar cell 200 of the embodiment also includes a solar cell with three or more solar cells joined together.

Since the band gap of the p-type light-absorbing layer (cuprous oxide) 3 of the first solar cell 100 of the first embodiment is about 2.0 [eV] or more and 2.2 [eV] or less, the band gap of the light-absorbing layer of the second solar cell 201 is preferably 1.0 [eV] or more and 1.6 [eV] or less. The light-absorbing layer of the second solar cell 201 is preferably one or more selected from the group consisting of a compound semiconductor layer selected from the group consisting of CIGS-type with a high In content ratio and CdTe-type, crystalline silicon, and a perovskite-type compound.

### Third Embodiment

A third embodiment relates to solar cell modules. FIG. 8 shows a schematic diagram of the solar cell module 300 of the third embodiment. The solar cell module 300 of FIG. 8 is a solar cell module consisting of a first solar cell module 301 and a second solar cell module 302 stacked together. The first solar cell module 301 is present light incident side and uses the solar cell 100 of the first embodiment. The second solar cell module 302 preferably uses the second solar cell 201.

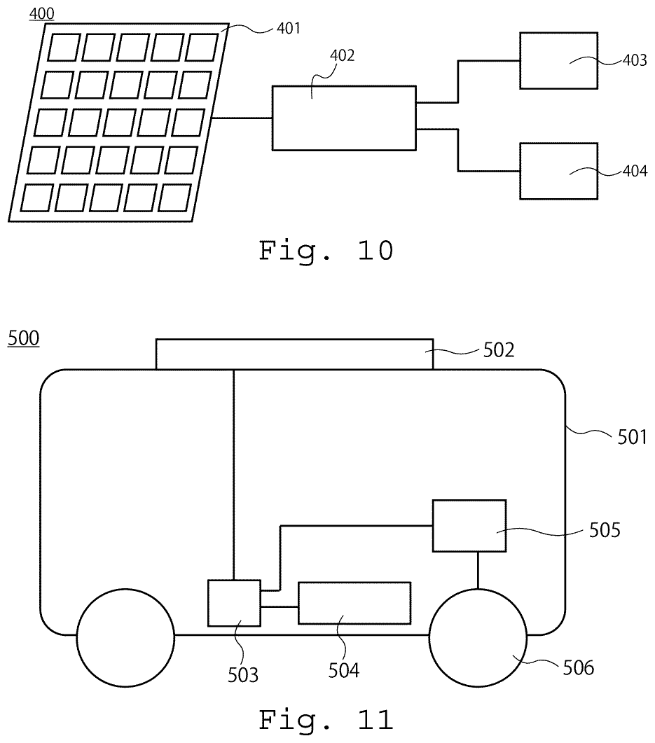

FIG. 9 shows a cross-sectional diagram of the solar cell module 300. In FIG. 9, the structure of the first solar cell module 301 is shown in detail, while the structure of the second solar cell module 302 is not shown. In the second solar cell module 302, the structure of the solar cell module is selected as appropriate depending on the light-absorbing layer and other factors of the solar cell to be used. The solar cell module 300 in FIG. 9 includes a plurality of submodules 303 surrounded by dashed lines in which a plurality of solar cells 100 (solar cells) are arranged in a horizontal direction and electrically connected in series by wiring 304, and a plurality of submodules 303 are electrically connected in parallel or in series. Adjacent submodules 303 are electrically connected by busbars 305.

In the adjacent solar cell 100, the n-electrode 5 on the upper side and the p-electrode 2 on the lower side are connected by wiring 304. Similar to the solar cell 100 of the first embodiment, the solar cell 100 of the third embodiment also has the substrate 1, the p-electrode 2, the p-type light-absorbing layer 3, the n-type layer 4, and the n-electrode 5 (the compound 6 of the first metal also included in the solar cell 100 of the third embodiment, but the compound 6 of the first metal is not shown in FIG. 9.). Both ends of the solar cell 100 in the submodule 303 are connected to a busbar 305, and the busbar 305 is preferably configured to electrically connect a plurality of submodules 303 in parallel or in series and to regulate the output voltage with the second solar cell module 302. The connection configuration of the solar cell 100 shown in the third embodiment is an example, and the solar cell module can be configured by other connection configurations.

### Fourth Embodiment

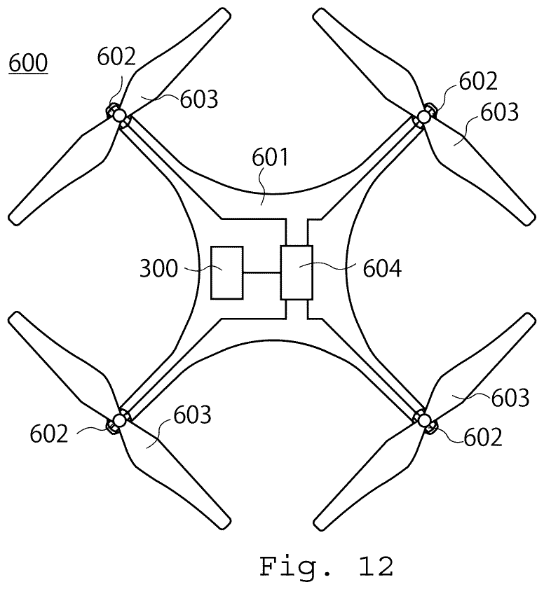

A fourth embodiment relates to a photovoltaic power generation system. The solar cell module of the fourth embodiment can be used as a generator that generates electric power in the photovoltaic power generation system of the fourth embodiment. The photovoltaic power generation system of the embodiment uses the solar cell module to generate electric power, specifically, it has a solar cell module that generates electric power, a converting element that converts the generated electric power, and a storage element that stores the generated electric power or a load that consumes the generated electric power. FIG. 10 shows a structural diagram of an embodiment of a photovoltaic power generation system 400. The photovoltaic system in FIG. 10 has a solar cell module 401 (300), a converter 402, a storage battery 403, and a load 404.

Either the storage battery 403 or the load 404 can be omitted. The load 404 may be configured to also use electrical power stored in the storage battery 403. The converter 402 is a device that includes circuits or elements that perform power conversion such as transformers and direct current to alternating current conversions such as DC-DC converters, DC-AC converters, and AC-AC converters. A suitable configuration of the converter 402 can be adopted according to the configuration of the power generation voltage, storage battery 403 and load 404.

The solar cells in the submodules 303 that receive light in the solar cell module 401 generate electric power, and the electric energy is converted by the converter 402 and stored in the storage battery 403 or consumed by the load 404. It is preferable to add a sunlight tracking system to the solar cell module 401 to constantly direct the solar cell module 401 to the sun, a solar collector to collect sunlight, or other devices to improve the efficiency of power generation.

The photovoltaic power generation system 400 is preferably used in residences, commercial facilities, factories, and other properties, or in movable property such as vehicles, aircraft, and electronic equipment. By virtue of using solar cells with excellent conversion efficiency of embodiments in solar cell modules, it is expected to increase the amount of electricity generated.

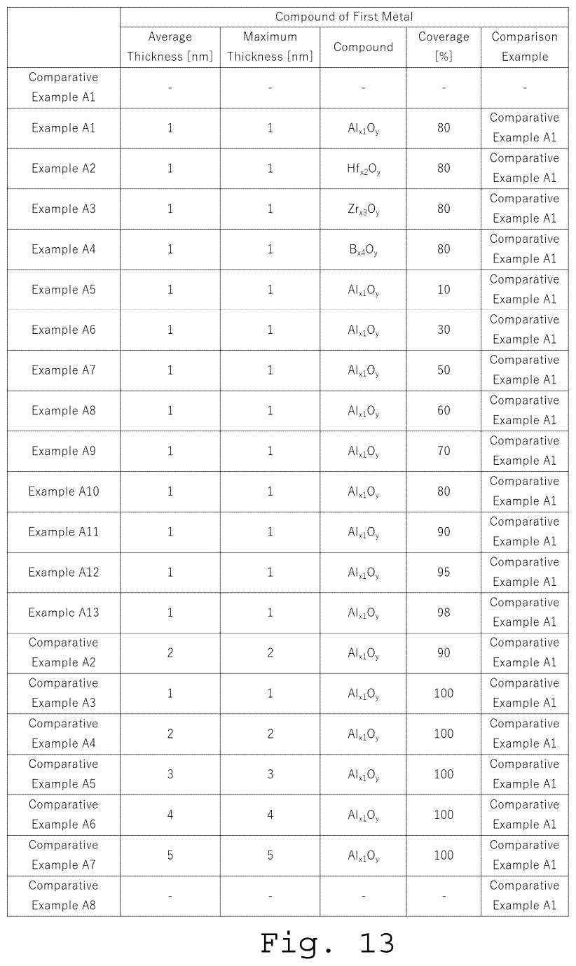

A vehicle is shown as an example of the use of the photovoltaic power generation system 400. FIG. 11 shows a conceptual diagram of a vehicle 500. The vehicle 500 shown in FIG. 11 has a vehicle body 501, a solar cell module 502, a power converter 503, a storage battery 504, a motor 505 and tires (wheels) 506. The power generated by the solar cell module 502 installed on the top of the vehicle body 501 is converted by the power converter 503 and charged by the storage battery 504 or consumed by the load such as the motor 505. The vehicle 500 can be moved by rotating the tires (wheels) 506 by the motor 505 using the power supplied from the solar cell module 502 or the storage battery 504. The solar cell module 502 may not be a multi-junction type but may consist only of a first solar cell module with the solar cell 100 or the like of the first embodiment. When a transparent solar cell module 502 is employed, it is also preferable to use the solar cell module 502 as a window to generate electricity on the sides of the vehicle body 501 in addition to the top of the vehicle body 501.

A flying object (drone) is shown as an example of the use of the photovoltaic power generation system 400. The flying object uses a solar cell module 401. The configuration of the flying object is briefly described using the schematic diagram of the flying object 600 shown in FIG. 12. The flying object 600 has a solar cell module 401, a frame 601, a motor 602, a rotary wing 603 and a control unit 604. The solar cell module 401, motor 602, rotary wing 603 and control unit 604 are located on the frame 601. The control unit 604 converts or adjusts the output power from the solar cell module 401. The motor 602 uses the power output from the solar cell module 401 to rotate the rotary wing 603. By virtue of applying the solar cell module 401 of the embodiment to the flying object 600, the flying object 600 that can fly using more power is provided.

Hereinafter, the invention will be described more specifically based on the examples, but the invention is not limited to the following examples.

### Example A

### Example A1

ITO (In:Sn=80:20, film thickness 150 nm) on a side in contact with glass and ATO (Sn:Sb=98:2, film thickness: 100 nm) are formed on an upper surface of a glass substrate 1 as the p-electrode 2 on a back surface side of a solar cell. A Cu₂O light-absorbing layer with a thickness of 6 [μm] (6 micrometre) is formed on the ATO film by a sputtering method in an oxygen and argon gas atmosphere. After forming of the p-type light-absorbing layer 3, Alₓ₁O_{y} is formed as the compound 6 of the first metal. After forming the compound of the first metal, Ga₂O₃ with a thickness of 10 [nm] as the n-type layer 4 is formed. Thereafter, the solar cell 100 is obtained by forming a transparent conductive film of AZO (ZnO:Al) with a thickness of 0.1 [μm] (0.1 micrometre) is formed as the n-electrode 5.

A solar simulator simulating a light source of 1.5G AM is used, and the light intensity is adjusted to 1 sun using a reference Si cell under that light source. Measurements are made under atmospheric pressure and the temperature in the measurement room is 25° C. [° C.] (degrees Celsius). The voltage is swept, and the current density (current divided by cell area) is measured. When the horizontal axis is voltage and the vertical axis is current density, the point of intersection with the horizontal axis is the open circuit voltage Voc. When the voltage and the current density are multiplied on a measurement curve and maximum points are Vmpp and Jmpp (maximum power point), respectively, FF=(Vmpp*Jmpp)/(Voc*Jsc), and a conversion efficiency Eff. is obtained by Eff.=Voc*Jsc*FF.

When the transmittance of light with wavelengths between 700 [nm] and 1000 [nm] is 75% or more and 100% or less, the evaluation rating is A. When the transmittance of light with wavelengths between 700 [nm] and 1000 [nm] is 70% or more and less than 75%, the evaluation rating is B. When the transmittance of light with wavelengths between 700 [nm] and 1000 [nm] is less than 70 [%], the evaluation rating is C. The evaluation of transmittance of light is common to Examples A and B.

When Jsc is 1.05 times or more of the Jsc of the comparison example, the evaluation rating is A. When Jsc is 1.00 times or more and less than 1.05 times of the Jsc of the comparison example, the evaluation rating is B. When Jsc is less than 1.00 times of the Jsc of the comparison example or more, the evaluation rating is C. The evaluation of Jsc is common to Examples A and B.

When Voc is 1.05 times or more of the Voc of the comparison example, the evaluation rating is A. When Voc is 1.00 times or more and less than 1.05 times of the Voc of the comparison example, the evaluation rating is B. When Voc is less than 1.00 times of the Voc of the comparison example or more, the evaluation rating is C. The evaluation of Voc is common to Examples A and B.

When FF is 1.01 times or more of the FF of the comparison example, the evaluation rating is A. When FF is 0.98 times or more and less than 1.01 times of the FF of the comparison example, the evaluation rating is B. When FF is less than 0.98 times of the FF of the comparison example or more, the evaluation rating is C. The Evaluation of FF is Common to Examples A and B.

When Eff. is 1.05 times or more of the Eff. of the comparison example, the evaluation rating is A. When Eff. is 1.00 times or more and less than 1.05 times of the Eff. of the comparison example, the evaluation rating is B. When Eff. is less than 1.00 times of the Eff. of the comparison example or more, the evaluation rating is C. The evaluation of Eff. is common to Examples A and B.

### Comparative Example A1

ITO (In:Sn=80:20, film thickness 150 nm) on a side in contact with glass and ATO (Sn:Sb=98:2, film thickness: 100 nm) are formed on an upper surface of a glass substrate 1 as the p-electrode 2 on a back surface side of a solar cell. A Cu₂O light-absorbing layer with a thickness of 6 [μm] (6 micrometre) is formed on the ATO film by a sputtering method in an oxygen and argon gas atmosphere. After forming the p-type light-absorbing layer 3, Ga₂O₃ with a thickness of 10 [nm] as the n-type layer 4 is formed directly on the p-type light-absorbing layer 3 without forming a thin Alₓ₁O_{y} by ALD method. Thereafter, the solar cell 100 is obtained by forming a transparent conductive film of AZO (Zno:Al) with a thickness of 0.1 [μm] (0.1 micrometre) is formed as the n-electrode 5. Additionally, the obtained solar cell is evaluated as the same manner as the example Al.

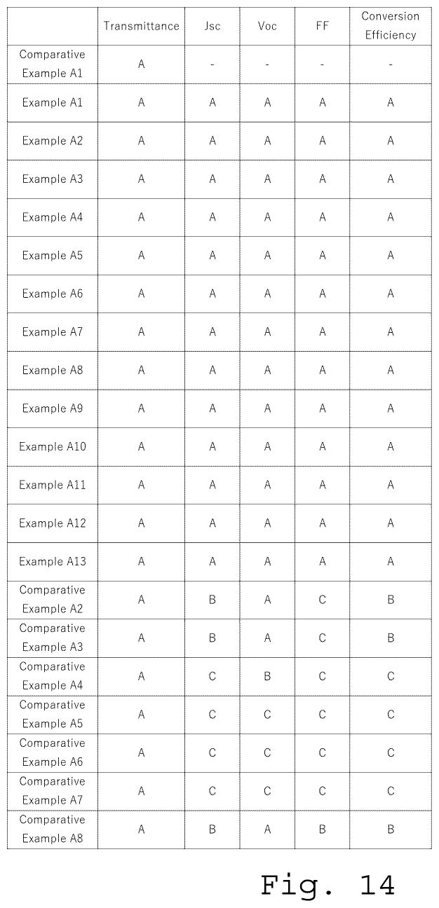

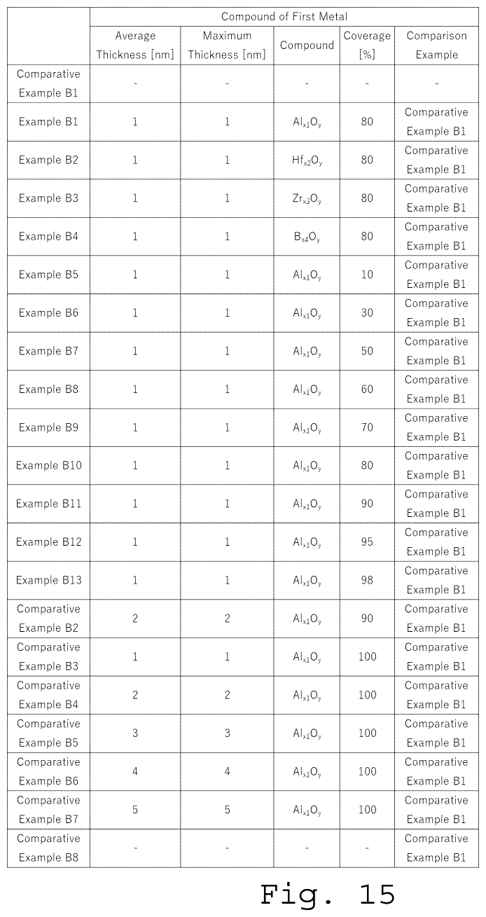

(Examples A2 to A13, Comparative Example A2 to A7) Solar cells 100 of Examples A2 to A13 and Comparative Examples A2 to A7 are manufactured by changing the conditions for the formation of the compound 6 of the first metal. The conditions for the compound 6 of the first metal of the solar cell of Example A are shown in the table in FIG. 13. The evaluation results of the solar cells of Example A are shown in the table in FIG. 14.

### Comparative Example A8

ITO (In:Sn=80:20, film thickness 150 nm) on a side in contact with glass and ATO (Sn:Sb=98:2, film thickness: 100 nm) are formed on an upper surface of a glass substrate 1 as the p-electrode 2 on a back surface side of a solar cell. A Cu₂O light-absorbing layer with a thickness of 6 [μm] (6 micrometre) is formed on the ATO film by a sputtering method in an oxygen and argon gas atmosphere. After depositing the p-type light-absorbing layer 3, Ga_{1.8}Al_{0.2}O₃ with a thickness of 10 [nm] as the n-type layer 4 is formed directly on the p-type light-absorbing layer 3 without forming a thin Alₓ₁O_{y} by ALD method. Thereafter, the solar cell 100 is obtained by forming a transparent conductive film of AZO (ZnO:Al) with a thickness of 0.1 [μm] (0.1 micrometre) is formed as the n-electrode 5. Additionally, the obtained solar cell is evaluated as the same manner as the example Al.

By virtue of forming the compound 6 of the first metal whose thickness is extremely thin with less than 100% coverage between the p-type light-absorbing layer 3 and the n-type layer 4, the oxygen draw-off from the p-type light-absorbing layer 3 by the n-type layer 4 can be reduced, and the defects derived from metallic Cu formed on the surface of the p-type light-absorbing layer 3 due to oxygen draw-off are reduced. Therefore, Voc is improved. However, when the coverage is 100% or exceeds 100%, FF and Jsc decrease due to the insulating property of the compound 6 of the first metal. Furthermore, as the thickness of the compound 6 of the first metal increases, in addition to FF and Jsc, Voc also decreases, which significantly degrades the conversion efficiency. Since the compound 6 of the first metal is wide bandgap and ultra-thin, the transmittance does not change.

### Example B

### Example B1

ITO (In:Sn=80:20, film thickness 150 nm) on a side in contact with glass and ATO (Sn:Sb=98:2, film thickness: 100 nm) are formed on an upper surface of a glass substrate 1 as the p-electrode 2 on a back surface side of a solar cell. A Cu₂O light-absorbing layer with a thickness of 6 [μm] (6 micrometre) is formed on the ATO film by a sputtering method in an oxygen and argon gas atmosphere. After forming of the p-type light-absorbing layer 3, Al O_{y} is formed as the compound 6 of the first metal. After forming the compound of the first metal, Ga₂O₃ with a thickness of 10 [nm] as the n-type layer 4 (the first n-type layer) is formed. ZnSnO (Zn:Sn=80:20) with a thickness of 14 [nm] as the second n-type layer is formed on the Ga₂O₃. Thereafter, the solar cell 100 is obtained by forming a transparent conductive film of AZO (ZnO:Al) with a thickness of 0.1 [μm] (0.1 micrometre) is formed as the n-electrode 5.

### Comparative Example B1

ITO (In:Sn=80:20, film thickness 150 nm) on a side in contact with glass and ATO (Sn:Sb=98:2, film thickness: 100 nm) are formed on an upper surface of a glass substrate 1 as the p-electrode 2 on a back surface side of a solar cell. A Cu₂O light-absorbing layer with a thickness of 6 [μm] (6 micrometre) is formed on the ATO film by a sputtering method in an oxygen and argon gas atmosphere. After forming the p-type light-absorbing layer 3, Ga O₃ with a thickness of 10 [nm] as the n-type layer 4 (the first n-type layer) is formed directly on the p-type light-absorbing layer 3 without forming a thin Alₓ₁O_{y} by ALD method. ZnSnO (Zn:Sn=80:20) with a thickness of 14 [nm] as the second n-type layer is formed on the Ga₂O₃. Thereafter, the solar cell 100 is obtained by forming a transparent conductive film of AZO (ZnO:Al) with a thickness of 0.1 [μm] (0.1 micrometre) is formed as the n-electrode 5. Additionally, the obtained solar cell is evaluated as the same manner as the example Al.

### Examples B2 to B13, Comparative Example B2 to B7

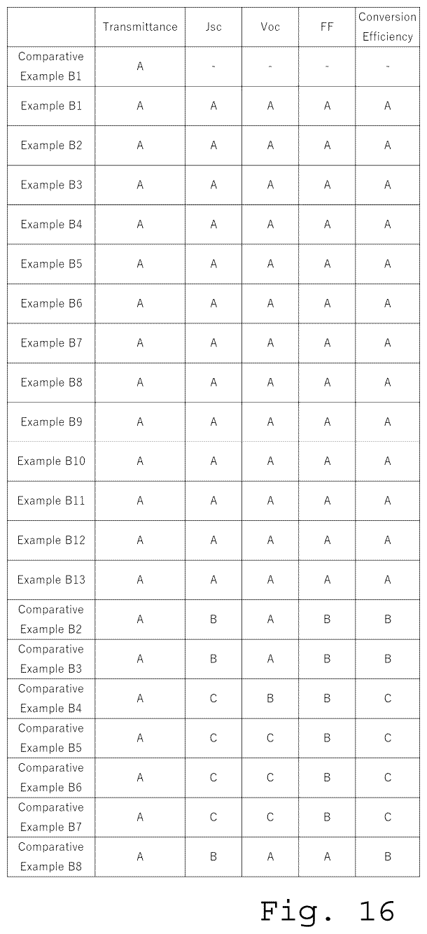

Solar cells 100 of Examples B2 to B13 and Comparative Examples B2 to B7 are manufactured by changing the conditions for the formation of the compound 6 of the first metal. The conditions for the compound 6 of the first metal of the solar cell of Example B are shown in the table in FIG. 15. The evaluation results of the solar cells of Example B are shown in the table in FIG. 16.

### Comparative Example B8

ITO (In:Sn=80:20, film thickness 150 nm) on a side in contact with glass and ATO (Sn:Sb=98:2, film thickness: 100 nm) are formed on an upper surface of a glass substrate 1 as the p-electrode 2 on a back surface side of a solar cell. A Cu₂O light-absorbing layer with a thickness of 6 [μm] (6 micrometre) is formed on the ATO film by a sputtering method in an oxygen and argon gas atmosphere. After depositing the p-type light-absorbing layer 3, Ga_{1.8}Al_{0.2}O₃ with a thickness of 10 [mm] as the n-type layer 4 is formed directly on the p-type light-absorbing layer 3 without forming a thin Alₓ₁O_{y} by ALD method. Thereafter, the solar cell 100 is obtained by forming a transparent conductive film of AZO (ZnO:Al) with a thickness of 0.1 [μm] (0.1 micrometre) is formed as the n-electrode 5. Additionally, the obtained solar cell is evaluated as the same manner as the example Al.

Compared to Example A, by virtue of forming the second n-layer having a smaller bandgap than the bandgap of the first n-type layer in Example B, the carrier recombination between the n-type layer 4 and the n-electrode 5 can be reduced, which contributes to improve FF. By virtue of forming the compound 6 of the first metal whose thickness is extremely thin with less than 100% coverage between the p-type light-absorbing layer 3 and the n-type layer 4, the oxygen draw-off from the p-type light-absorbing layer 3 by the n-type layer 4 can be reduced, and the defects derived from metallic Cu formed on the surface of the p-type light-absorbing layer 3 due to oxygen draw-off are reduced. Therefore, Voc is improved. However, when the coverage is 100%, FF and Jsc decrease due to the insulating property of the compound 6 of the first metal. Furthermore, as the thickness of the compound 6 of the first metal increases, in addition to FF and Jsc, Voc also decreases, which significantly degrades the conversion efficiency. Since the compound 6 of the first metal is wide bandgap and ultra-thin, the transmittance does not change.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

In the specification, some elements are represented only by chemical symbols for elements.

Hereinafter, clauses of embodiments are additionally noted.

### Clause 1

A solar cell comprising:
a p-electrode;
an n-electrode;
a p-type light-absorbing layer provided on the p-electrode and being mainly composed of a cuprous oxide compound;
an n-type layer disposed between the p-type light-absorbing layer and the n-electrode; and
a compound of first metal provided between the p-type light-absorbing layer and the n-type layer;
wherein coverage of the compound of the first metal covering the p-type light absorption layer is 10% or more and less than 100%,
the first metal is one or more elements selected from the group consisting of Al, Hf, Zr, and B, and
the cuprous oxide compound is in direct contact with the compound of the first metal and the n-type layer.

### Clause 2

The solar cell according to clause 1, wherein
the compound of the first metal is a compound represented by Alₓ₁Hfₓ₂Zrₓ₃Bₓ₄O_{y},
x1, x2, x3, and x4 satisfy 0.8≤x1+x2+x3+x4≤1.2, and x1, x2, x3, x4, and y satisfy 0.3≤(x1+x2+x3+x4)/y≤0.8.

### Clause 3

The solar cell according to clause 1, wherein
the compound of the first metal is a compound represented by Alₓ₁O_{y}, and
x1 and y satisfy 0.5≤x1/y≤0.8.

### Clause 4

The solar cell according to clause 1, wherein
the compound of the first metal is a compound represented by Hfₓ₂O_{y}, and
x2 and y satisfy 0.3≤x2/y≤0.7.

### Clause 5

The solar cell according to clause 1, wherein
the compound of the first metal is a compound represented by Zrₓ₃O_{y}, and
x3 and y satisfy 0.3≤x3/y≤0.7.

### Clause 6

The solar cell according to clause 1, wherein
the compound of the first metal is a compound represented by Bₓ₄O_{y}, and
x4 and y satisfy 0.5≤x4/y≤0.8.

### Clause 7

The solar cell according to any one of clauses 1 to 6, wherein
the cuprous oxide compound has cuprite structure.

### Clause 8

The solar cell according to any one of clauses 1 to 7, wherein
the coverage is 50% or more and less than 100%.

### Clause 9

The solar cell according to any one of clauses 1 to 8, wherein
the coverage is 60% or more and less than 100%.

### Clause 10

The solar cell according to any one of clauses 1 to 9, wherein
an average thickness of the compound of the first metal is 0.2 [nm] or more and 1 [nm] or less.

### Clause 11

The solar cell according to any one of clauses 1 to 10, wherein a maximum thickness of the compound 6 of the first metal is 0.2 [nm] or more and 1 [nm] or less.

### Clause 12

The solar cell according to any one of clauses 1 to 11, wherein a side surface of the compound of the first metal is in direct contact with the n-type layer.

### Clause 13

The solar cell according to any one of clauses 1 to 12, wherein
one or more side surfaces of the compound of the first metal which does not face the p-type light-absorbing layer are in direct contact with the n-type layer.

### Clause 14

The solar cell according to any one of clauses 1 to 13, wherein
every side surface of the compound of the first metal which does not face the p-type light-absorbing layer is in direct contact with the n-type layer.

### Clause 15

A multi-junction solar cell comprising:
the solar cell according to any one of clauses 1 to 14.

### Clause 16

A solar cell module comprising:
the solar cell according to any one of clauses 1 to 14.

### Clause 17

A photovoltaic power generation system comprising:
the solar cell module according to clause 16 which generates electric power.

What is claimed is:

1. A solar cell comprising:
a p-electrode;
an n-electrode;
a p-type light-absorbing layer provided on the p-electrode and being mainly composed of a cuprous oxide compound;
an n-type layer disposed between the p-type light-absorbing layer and the n-electrode; and
a compound of first metal provided between the p-type light-absorbing layer and the n-type layer;
wherein coverage of the compound of the first metal covering the p-type light absorption layer is 10% or more and less than 100%,
the first metal is one or more elements selected from the group consisting of Al, Hf, Zr, and B, and
the cuprous oxide compound is in direct contact with the compound of the first metal and the n-type layer.

2. The solar cell according to claim 1, wherein
the compound of the first metal is a compound represented by Alₓ₁Hfₓ₂Zrₓ₃Bₓ₄O_{y},
x1, x2, x3, and x4 satisfy 0.8≤x1+x2+x3+x4≤1.2, and
x1, x2, x3, x4, and y satisfy 0.3≤(x1+x2+x3+x4)/y≤0.8.

3. The solar cell according to claim 1, wherein
the compound of the first metal is a compound represented by Alₓ₁O_{y}, and
x1 and y satisfy 0.5≤x1/y≤0.8.

4. The solar cell according to claim 1, wherein
the compound of the first metal is a compound represented by Hfₓ₂O_{y}, and
x2 and y satisfy 0.3≤x2/y≤0.7.

5. The solar cell according to claim 1, wherein
the compound of the first metal is a compound represented by Zrₓ₃O_{y}, and
x3 and y satisfy 0.3≤x3/y≤0.7.

6. The solar cell according to claim 1, wherein
the compound of the first metal is a compound represented by Bₓ₄O_{y}, and
x4 and y satisfy 0.5≤x4/y≤0.8.

7. The solar cell according to claim 1, wherein
the cuprous oxide compound has cuprite structure.

8. The solar cell according to claim 1, wherein
the coverage is 50% or more and less than 100%.

9. The solar cell according to claim 1, wherein
the coverage is 60% or more and less than 100%.

10. The solar cell according to claim 1, wherein
an average thickness of the compound of the first metal is 0.2 [nm] or more and 1 [nm] or less.

11. The solar cell according to claim 1, wherein
a maximum thickness of the compound 6 of the first metal is 0.2 [nm] or more and 1 [nm] or less.

12. The solar cell according to claim 1, wherein
a side surface of the compound of the first metal is in direct contact with the n-type layer.

13. The solar cell according to claim 1, wherein
one or more side surfaces of the compound of the first metal which does not face the p-type light-absorbing layer are in direct contact with the n-type layer.

14. A multi-junction solar cell comprising:
the solar cell according to claim 1.

15. A solar cell module comprising:
the solar cell according to claim 1.

16. A photovoltaic power generation system comprising:
the solar cell module according to claim 15 which generates electric power.
